(19) United States
(12) Patent Application Publication
(10) Pub. No.: US 2017/0053781 A1
(43) Pub. Date: Feb. 23, 2017

(54) Multi-Station Chamber Having Symmetric Grounding Plate

(71) Applicant: Lam Research Corporation, Fremont, CA (US)

(72) Inventors: Adrien Lavoie, Newberg, OR (US); Shankar Swaminathan, Beaverton, OR (US); Ramesh Chandrasekharan, Portland, OR (US); Jennifer Petraglia, Portland, OR (US); Shawn Hamilton, Boulder Creek, CA (US)

(21) Appl. No.: 14/839,675

(22) Filed: Aug. 28, 2015

Related U.S. Application Data
(60) Provisional application No. 62/206,829, filed on Aug. 18, 2015.

(51) Int. Cl. H01J 37/32

(52) U.S. Cl. CPC H01J 37/32458; H01J 37/3244; H01J 37/32715; H01J 37/32743; H01J 37/32788; H01J 37/32834; H01J 2237/3321; H01J 2237/3323

(57) ABSTRACT

A multi-station chamber having a symmetric ground plate is disclosed. The multi-station chamber includes four stations, and the four stations are arranged in a square configuration with a rotating mechanism in a center location. A pedestal for supporting a substrate is provided for each of the four stations, each pedestal is disposed in a lower chamber body, and each pedestal includes a carrier ring. The lower chamber body includes outer walls and inner walls to define a space for each of the pedestals of the four chambers. A ground plate is disposed over the inner walls and attached to the outer walls. The ground plate has a center opening and a process opening for each station. The center opening is configured to receive the rotating mechanism at the center location. The process opening has a diameter that is larger than a diameter of the carrier ring at each station, and a symmetric gap is defined between an edge of each process opening defined by the ground plate and an outer edge of a carrier ring. For applied radio frequency power, an RF ground return is provided via the ground plate that symmetrically surrounds each process opening of each station.

### CLAIM OF PRIORITY

This application claims priority from U.S. Provisional Patent Application No. 62/206,829, filed Aug. 18, 2015, and entitled “MULTI-STATION CHAMBER HAVING SYMMETRIC GROUNDING PLATE.” This provisional application is herein incorporated by reference.

### FIELD OF THE DISCLOSURE

The present embodiments relate to semiconductor wafer processing equipment tools, and more particularly, multi-station chambers with symmetric grounding plate for improved wafer-to-wafer non-uniformity matching.

### DESCRIPTION OF THE RELATED ART

There are many types of film deposition processes commonly used in the semiconductor fabrication field. One example process is referred to as a plasma-enhanced chemical vapor deposition (PECVD), which is a type of plasma deposition that is used to deposit thin films from a gas state (i.e., vapor) to a solid state on a substrate such as a wafer. PECVD systems convert a liquid precursor into a vapor precursor, which is delivered to a chamber. PECVD systems may include a vaporizer that vaporizes the liquid precursor in a controlled manner to generate the vapor precursor.

Another example film deposition process is referred to as atomic layer deposition (ALD), which also utilizes plasma energy to facilitate the deposition. ALD systems are used to produce very thin films that are highly conformal, smooth, and possess excellent physical properties. ALD uses volatile gases, solids, or vapors that are sequentially introduced (or pulsed) over a heated substrate. A first precursor is introduced as a gas, which is absorbed (or adsorbed) into the substrate and the reactor chamber is cleared of the gaseous precursor. A second precursor is introduced as a gas, which reacts with the absorbed precursor to form a monolayer of the desired material. By regulating this sequence, the films produced by ALD are deposited a monolayer at a time by repeatedly switching the sequential flow of two or more reactive gases over the substrate.

Chambers used to process PECVD and ALD processes require highly engineered structural construction so that the resulting films deposited on substrates are as uniform as possible and processes are repeatable from wafer-to-wafer. In such chambers, radio frequency (RF) power is supplied to enable excitation of gases in the form of a plasma, which leads to the deposition of a material film. The delivery of RF power is typically applied to either the substrate support (i.e., the pedestal) or the showerhead. In either configuration, RF power applied to the chamber needs to have an RF return to ground. Commonly, the chamber walls are grounded and RF power turns to ground via one or more conductive paths.

This process has worked well for some time, but as the demand continues to push for the manufacture of smaller feature sizes, more stringent demands are continually made upon chamber construction and engineered geometries. For example, some chamber designs usable for PECVD as well as ALD include multi-station designs. Multi-station designs are those that enable deposition processes to occur in multiple stations at the same time. Such multi-station designs have added complexities associated with neighboring processing by other stations. Furthermore, the RF return to ground from the individual stations may not be symmetric, which may introduce additional challenges in overcoming inherent wafer-to-wafer non-uniformity mismatch.

It is in this context that inventions arise.

### SUMMARY

Embodiments of the disclosure provide embodiments of a process chamber, used for processing semiconductor wafers. In one implementation, a ground plate is provided that provides for symmetric radio frequency (RF) ground return paths during processing, such as thin film deposition processing in plasma chambers.

A multi-station chamber having a symmetric ground plate is disclosed. The multi-station chamber includes four stations, and the four stations are arranged in a square configuration with a rotating mechanism in a center location. A pedestal for supporting a substrate is provided for each of the four stations, each pedestal is disposed in a lower chamber body, and each pedestal includes a carrier ring. In some embodiments, the carrier ring is referred to as a plasma focus ring. The lower chamber body includes outer walls and inner walls to define a space for each of the pedestals of the four chambers. A ground plate is disposed over the inner walls and attached to the outer walls. The ground plate has a center opening and a process opening for each station. The center opening is configured to receive the rotating mechanism at the center location. The process opening has a diameter that is larger than a diameter of the carrier ring at each station, and a symmetric gap is defined between an edge of each process opening defined by the ground plate and an outer edge of a carrier ring. The chamber further includes an upper chamber body. The upper chamber body is configured to mate over the lower chamber body. The upper chamber body includes four showerheads and each of the four showerheads is configured to be aligned over a respective pedestal of a respective station. Wherein when a radio frequency (RF) power is provided to either the showerhead or the pedestal of each station, the RF power is provided with an RF ground return via the ground plate that symmetrically surrounds each process opening of each station.

In some embodiments, a top surface of the ground plate is positioned at a first height relative to an inner floor of the lower chamber. The first height is about equal to or slightly less than a second height of a top surface of the pedestal relative to the inner floor of the lower chamber. A top surface of a substrate when present over any one of the four stations is substantially coplanar with the top surface of the ground plate.

In some embodiments, the ground plate covers a top surface of the lower chamber, except for the center opening and the process opening for each station.

In some embodiments, the rotating mechanism includes a plurality of spider forks, and each of the spider forks is associated with each of the four of stations and is configured to lift and move a respective one of carrier rings from each station in order to lift and move a respective substrate when present over a respective pedestal.

In some embodiments, the symmetric gap provides a separation to a ground potential provided by the ground plate, the ground potential is symmetrically arranged around each substrate when disposed over a respective pedestal of each station.

In some embodiments, a pump is disposed below the lower chamber body. The pump is configured to provide evacuation of process gases from a space between the inner floor and an under surface of the ground plate. Further, process gases flow through the gap at each station that is symmetrically maintained around and between the process openings in the ground plate and the carrier ring of each station.

In some embodiments, two pumps are provided in a symmetric orientation below the lower chamber body.

In another embodiment, a multi-station chamber is disclosed. The multi-station chamber includes a lower chamber body that has a plurality of stations arranged around a rotating mechanism. Each station includes a pedestal for supporting a substrate and a carrier ring that surrounds the pedestal. The carrier ring of each station is configured to be lifted and moved by the rotating mechanism. The lower chamber body has an inner floor disposed below each pedestal of each of the plurality of stations. The lower chamber body has outer walls that surround a perimeter of each of the plurality of stations. The outer walls have a support step. The lower chamber body has inner walls that laterally separate respective ones of the plurality of stations. The outer walls and the inner walls extend up from the inner floor. The chamber further includes a ground plate disposed over the support step of the outer walls and over the inner walls. The ground plate has a center opening and a process opening for each station. The process opening defined for each pedestal has the carrier ring. The process opening surrounds the carrier ring of each process station so that gap is symmetrically maintained around and between the ground plate and the carrier ring of each station. Wherein the ground plate provides a symmetric RF return path to ground for RF power supplied to any one of the stations of the multi-station chamber.

One advantage of providing a symmetric RF return path to ground is that deposition of ALD films results in substantial reductions in wafer-to-wafer (WtW) non-uniformity mismatch. Without being bound by theory, it has been hypothesized that this mismatch was due to differences in RF or thermal grounding for each station. Integration of a symmetric grounding plate has resulted in improved WtW matching. These and other advantages will be discussed below and will be appreciated by those skilled in the art upon reading the specification, drawings and the claims.

### BRIEF DESCRIPTION OF THE DRAWINGS

FIG. 1 illustrates a substrate processing system, which is used to process a wafer, e.g., to form films thereon.

FIG. 2 illustrates a top view of a multi-station processing tool, wherein four processing stations are provided, in accordance with one embodiment.

FIG. 3 shows a schematic view of an embodiment of a multi-station processing tool with an inbound load lock and an outbound load lock, in accordance with one embodiment.

FIGS. 4A-4B illustrate cross-section views of the multi-station chamber, wherein a ground plate is provided for RF return symmetry.

FIGS. 5A-5B illustrate example configurations of the ground plate, in accordance with one embodiment.

FIGS. 5C-5D illustrate three-dimensional views of the ground plate installed in a multi-station chamber.

FIG. 6 illustrates an example cross-section of a portion of the chamber, showing example dimensions.

FIGS. 7A-7C illustrate example test data, representing substantial improvements in wafer-to-wafer uniformity across stations of a multi-station chamber.

FIG. 8 shows a control module for controlling the systems, in accordance with one embodiment.

### DESCRIPTION

Embodiments of the disclosure provide embodiments of a process chamber, used for processing semiconductor wafers. A ground plate is disclosed that is configured to symmetrically surround each station of a multi-station chamber, such that a symmetric radio frequency (RF) return to ground is provided around each station. The symmetry provided by the ground plate enables for uniform processing of thin films being deposited and also improves station-to-station uniformity as well as wafer-to-wafer uniformity.

In one embodiment, a multi-station chamber having a symmetric ground plate is disclosed. The multi-station chamber includes four stations, and the four stations are arranged in a square configuration with a rotating mechanism in a center location. A pedestal for supporting a substrate is provided for each of the four stations, each pedestal is disposed in a lower chamber body, and each pedestal includes a carrier ring. The lower chamber body includes outer walls and inner walls to define a space for each of the pedestals of the four chambers. A ground plate is disposed over the inner walls and attached to the outer walls. The ground plate has a center opening and a process opening for each station. The center opening is configured to receive the rotating mechanism at the center location. The process opening has a diameter that is larger than a diameter of the carrier ring at each station, and a symmetric gap is defined between an edge of each process opening defined by the ground plate and an outer edge of a carrier ring. For applied radio frequency power, an RF ground return is provided via the ground plate that symmetrically surrounds each process opening of each station.

In one configuration, a chamber then will include four spider forks and a carrier ring will be disposed around respective pedestals of each of the stations. In this configuration, the spider forks can simultaneously lift each of the four carrier rings (and any wafer disposed thereon), and rotate all of the carrier rings and wafers to the next station (e.g., for additional or different processing). In one configuration, the chamber has loading and unloading stations when one wafer is loaded at a time or can include parallel loading and unloading stations where two wafers are loaded and unloaded at a time. As noted above, in some embodiments, the carrier ring may be referred to as a plasma focus ring. In such embodiments, the plasma focus ring functions to focus or optimize the plasma processing across the surface of the substrate, including the edges of the substrate. Generally speaking a plasma focus ring works to extend the outer surface of the substrate so that non-uniformities due to the substrate edge are extended to the outer surface edge of the plasma focus ring (i.e., instead of the substrate edge). In this manner, the edge of the substrate is more uniformly processed, as it will see less or reduced process non-uniformities.

It should be appreciated that the present embodiments can be implemented in numerous ways, such as a process, an apparatus, a system, a device, or a method. Several embodiments are described below.

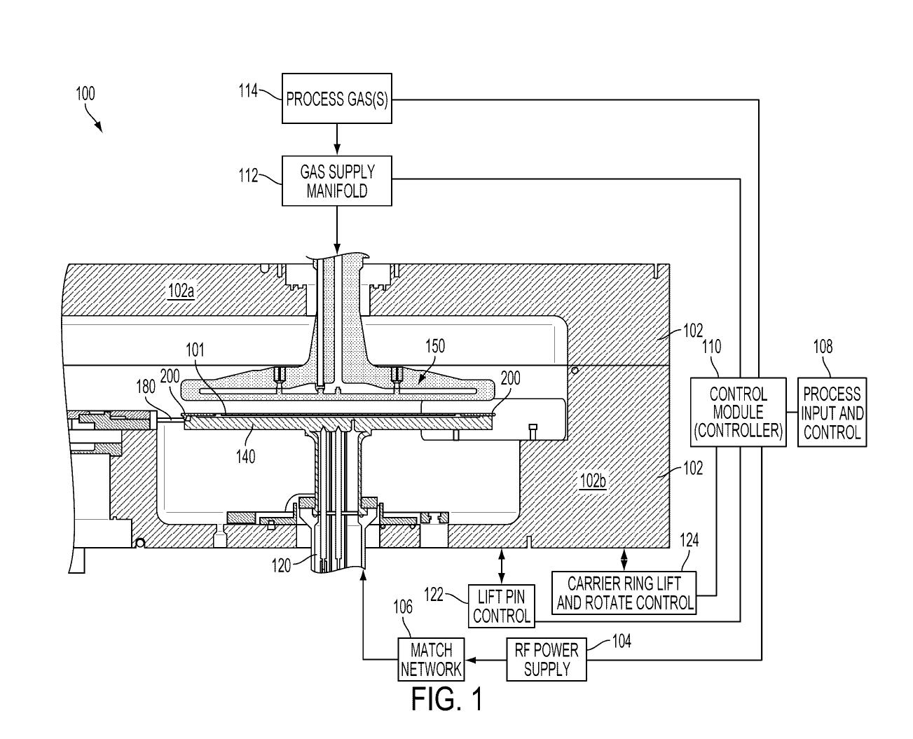

FIG. 1 illustrates a substrate processing system 100, which is used to process a wafer 101. The system includes a chamber 102 having a lower chamber body 102b and an upper chamber body 102a. A center column is configured to support a pedestal 140, which in one embodiment is a powered electrode. The pedestal 140 is electrically coupled to power supply 104 via a match network 106. The power supply is controlled by a control module 110, e.g., a controller. The control module 110 is configured to operate the substrate processing system 100 by executing process input and control 108. The process input and control 108 may include process recipes, such as power levels, timing parameters, process gases, mechanical movement of the wafer 101, etc., such as to deposit or form films over the wafer 101 via ALD methods or PECVD methods.

The center column is also shown to include lift pins 120, which are controlled by lift pin control 122. The lift pins 120 are used to raise the wafer 101 from the pedestal 140 to allow an end-effector to pick the wafer and to lower the wafer 101 after being placed by the end end-effector. The substrate processing system 100 further includes a gas supply manifold 112 that is connected to process gases 114, e.g., gas chemistry supplies from a facility. Depending on the processing being performed, the control module 110 controls the delivery of process gases 114 via the gas supply manifold 112. The chosen gases are then flown into the shower head 150 and distributed in a space volume defined between the showerhead 150 face that faces that wafer 101 and the wafer 101 resting over the pedestal 140.

Further, the gases may be premixed or not. Appropriate valving and mass flow control mechanisms may be employed to ensure that the correct gases are delivered during the deposition and plasma treatment phases of the process. Process gases exit chamber via an outlet. A vacuum pump (e.g., a one or two stage mechanical dry pump and/or a turbomolecular pump) draws process gases out and maintains a suitably low pressure within the reactor by a close loop controlled flow restriction device, such as a throttle valve or a pendulum valve.

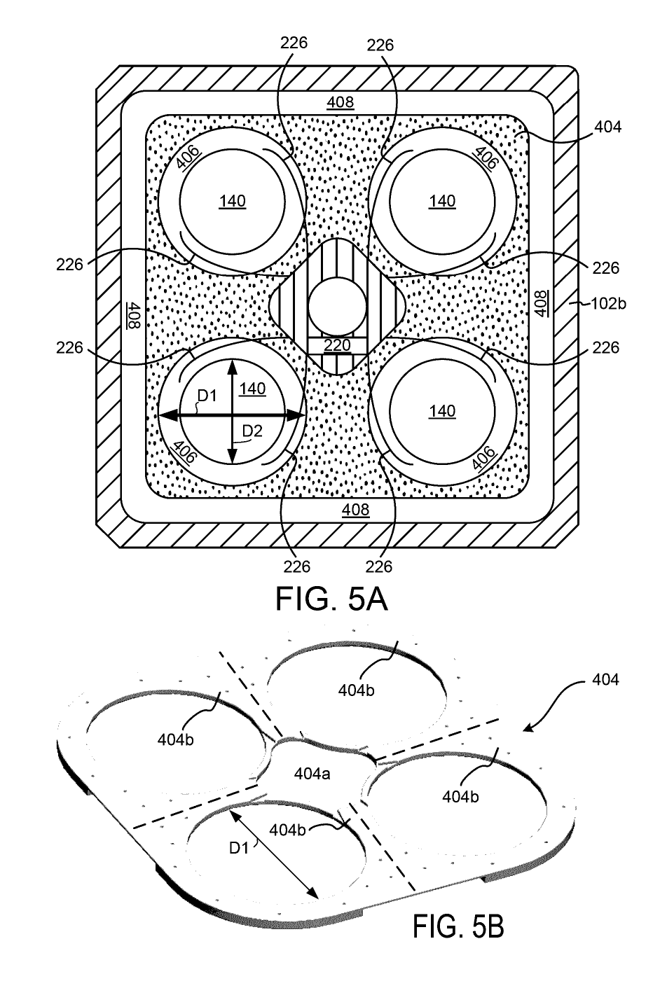

Also shown is a carrier ring 200 that encircles an outer region of the pedestal 140. The carrier ring 200 is configured to sit over a carrier ring support region that is a step down from a wafer support region in the center of the pedestal 140. The carrier ring includes an outer edge side of its disk structure, e.g., outer radius, and a wafer edge side of its disk structure, e.g., inner radius, that is closest to where the wafer 101 sits. The wafer edge side of the carrier ring includes a plurality of contact support structures which are configured to lift the wafer 101 when the carrier ring 200 is lifted by spider forks 226. The carrier ring 200 is therefore lifted along with the wafer 101 and can be rotated to another station, e.g., in a multi-station system. More detail regarding the ground plate used to improve symmetric RF ground return is provided below with reference to FIGS. 4B-7C.

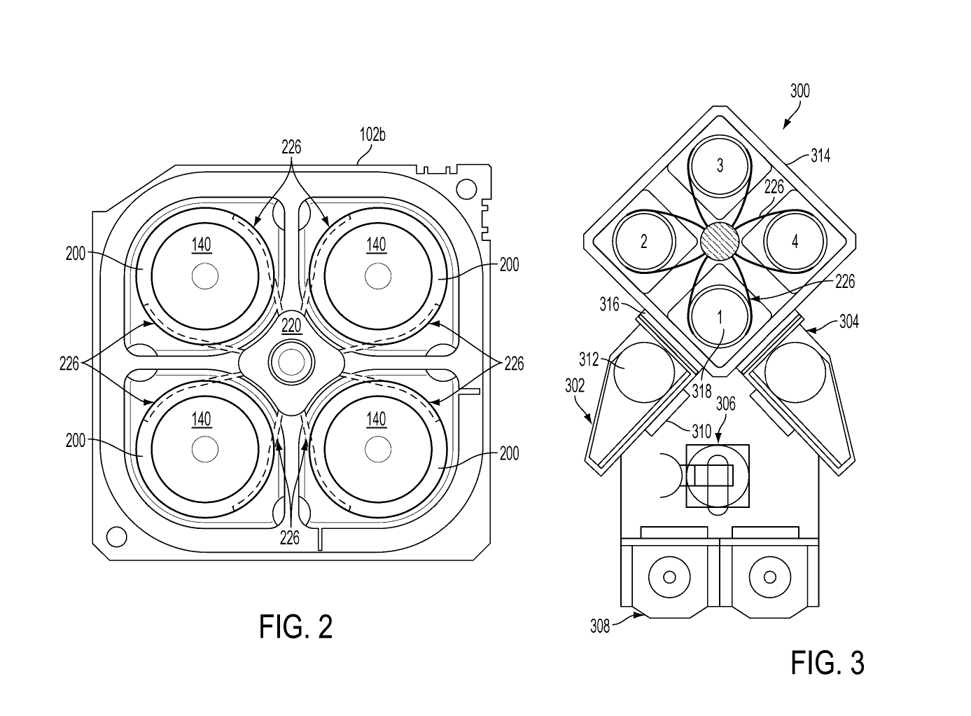

FIG. 2 illustrates a top view of a multi-station processing tool, wherein four processing stations are provided. This top view is of the lower chamber body 102b (e.g., with the top chamber portion 102a removed for illustration), wherein four stations are accessed by spider forks 226. Each spider fork or fork includes a first and second arm, each of which is positioned around a portion of each side of the pedestal 140. In this view, the spider forks 226 are drawn in dash-lines, to convey that they are below the carrier ring 200. The spider forks 226, coupled to a rotating mechanism 220, are configured to raise up and lift the carrier rings 200 (i.e., from a lower surface of the carrier rings 200) from the stations simultaneously, and then rotate at least one or more stations before lowering the carrier rings 200 (where at least one of the carrier rings supports a wafer 101) to a next location so that further plasma processing, treatment and/or film deposition can take place on respective wafers 101.

In this illustration, a grounding plate 290 is provided. However, grounding plate 290 has a non-symmetric configuration around the pedestal 140. As shown, grounding plate 290 has portions 290a and 290b that non-symmetrically extend a body of ground away from the pedestal 140. Portions 290c and 290d have a thinner separation with less body for providing ground return to RF power. As such, this configuration, although useful for some processes, is not optimized for efficient and symmetric RF ground return, especially in more demanding ALD processes that require ever stringent film performance.

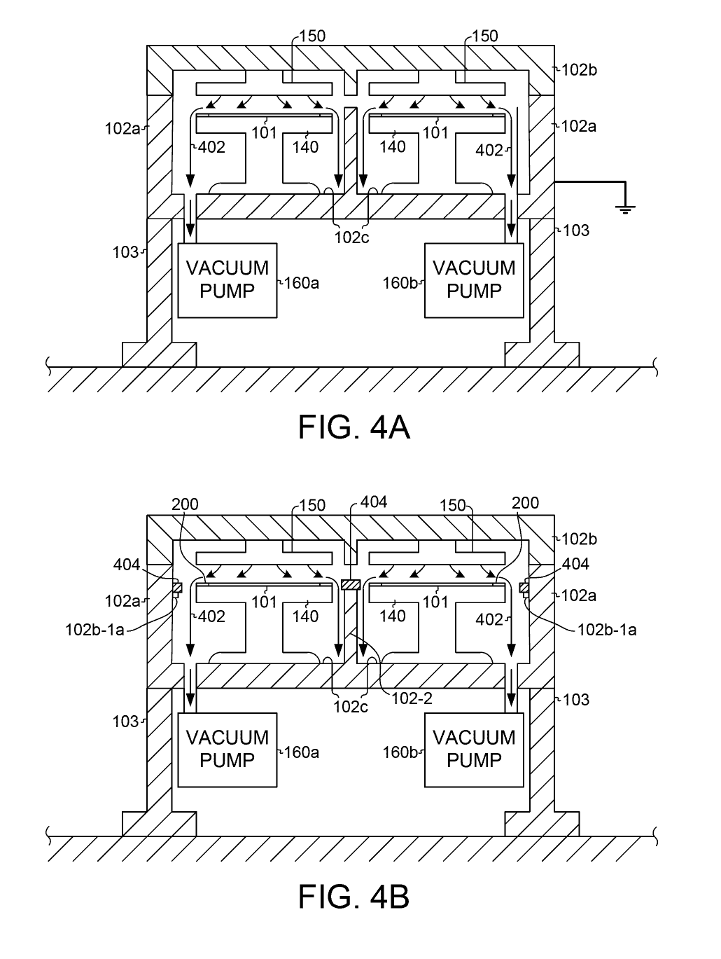

FIG. 3 shows a schematic view of an embodiment of a multi-station processing tool 300 with an inbound load lock 302 and an outbound load lock 304. A robot 306, at atmospheric pressure, is configured to move substrates from a cassette loaded through a pod 308 into inbound load lock 302 via an atmospheric port 310. Inbound load lock 302 is coupled to a vacuum source (not shown) so that, when atmospheric port 310 is closed, inbound load lock 302 may be pumped down. Inbound load lock 302 also includes a chamber transport port 316 interfaced with processing chamber 102b. Thus, when chamber transport 316 is opened, another robot (not shown) may move the substrate from inbound load lock 302 to a pedestal 140 of a first process station for processing.

The depicted processing chamber 102b comprises four process stations, numbered from 1 to 4 in the embodiment shown in FIG. 3. In some embodiments, processing chamber 102b may be configured to maintain a low pressure environment so that substrates may be transferred using a carrier ring 200 among the process stations without experiencing a vacuum break and/or air exposure. Each process station depicted in FIG. 3 includes a process station substrate holder (shown at 318 for station 1) and process gas delivery line inlets.

FIG. 3 also depicts spider forks 226 for transferring substrates within processing chamber 102b. As will be described in more detail below, the spider forks 226 rotate and enable transfer of wafers from one station to another. The transfer occurs by enabling the spider forks 226 to lift carrier rings 200 from an outer undersurface, which lifts the wafer, and rotates the wafer and carrier together to the next station. In one configuration, the spider forks 226 are made from a ceramic material to withstand high levels of heat during processing.

In the configuration of FIG. 3, no grounding plate is provided around each of the pedestals. As such, the lower chamber body is left exposed and the RF ground return is usually via chamber walls. This configuration does not provide any symmetry for RF ground return.

In some embodiments, a “ring-less” substrate transfer may also be employed. In such embodiments, the “carrier ring” or “plasma focusing ring” remains fixed on one station. The substrate is moved by lifting the substrate off of the pedestal with pins, inserting a paddle under the wafer, and then lowering the substrate on pins thus ensuring direct contact with the paddle to substrate. At this point, the substrate is indexed using the paddle to another station. Once the substrate is at the new station, the substrate is lifted off of the paddle with pins, the paddle is rotated or moved out and the pins are lowered ensure direct contact of the substrate to the pedestal. Now, the substrate processing can proceed at the new station for the indexed (i.e., moved) substrate. When the system has multiple stations, each of the substrates (i.e., those present at stations) can be transferred together, e.g., simultaneously, in the similar fashion for ring-less substrate transfers.

FIG. 4A illustrates a cross-sectional view of the multi-station chamber, in accordance with one embodiment. The chamber includes the lower chamber body 102a and the upper chamber body 102b. The upper chamber body 102b is configured to lower the showerhead 150, such that the showerheads 150 are substantially aligned over the pedestal 140 of each station. The lower chamber body 102a is configured to be supported by a support structure 103. The support structure 103 may be defined by any suitable structure capable of supporting the multi-station chamber 102, as well as facilities utilized to provide gases, RF power, pressure control, temperature control, timing, and associated controller and electronics. In one embodiment, the support structure 103 is defined from a metal tubular structure, which supports the chamber above the surface (e.g., clean room floor) in which the chamber is installed.

FIG. 4B illustrates the similar configuration shown in FIG. 4A, except for the addition of a ground plate 404. Grounded plate 404 is provided such that it sits within the lower chamber body 102a. In one embodiment, the ground plate 404 will at least partially sit over an inner wall 102b-2, and supported by the outer wall 102b-1. In one embodiment, the outer wall 102b-1 will also include a support step 102b-1a over which the ground plate 404 is attached. In this configuration, the ground plate 404 is provided such that a symmetric distribution of the ground potential via the ground plate is provided around each one of the stations, which include a respective pedestal 140, and the carrier rings 200. In one configuration, a gap is symmetrically defined between the outside edge of the carrier ring 200 and the inside edge of the ground plate 404.

In this illustration, the showerhead 150 is configured to deliver deposition gases in accordance with the desired deposition process. The deposition gases, depending on the deposition process (e.g. PECVD, ALD, etc.) will be disposed over the surface of the substrate 101. When plasma is activated by the delivery of RF power, the deposition gases will be activated to cause the formation of a film. In some processes, the deposition process includes a number of steps, such as reactant absorption, purge, and plasma activated deposition reactants. Vacuum pumps 160a and 160b are provided and interfaced with the lower chamber body 102a. The vacuum pumps 160 are configured to provide for sufficient gas flow to remove process gases and/or to provide pressure control within the chamber. Typically, the gas flow is allowed to flow over the substrate 101 and over the edges of the pedestal 140, thus defining flows 402. As will be defined below in more detail, a process opening is defined as a circular opening in the ground plate 404 around each one of the stations, such that the gap between the inner edge of the process opening of the ground plate 404 and the outside edge of the pedestal 140 that includes the carrier ring 200 is provided. The gap is configured so that a gas flow is still provided along 402, while also providing for a uniform coupling of RF power return to ground, once RF power is provided to either the pedestal 140 or the showerhead 150, depending on the configuration.

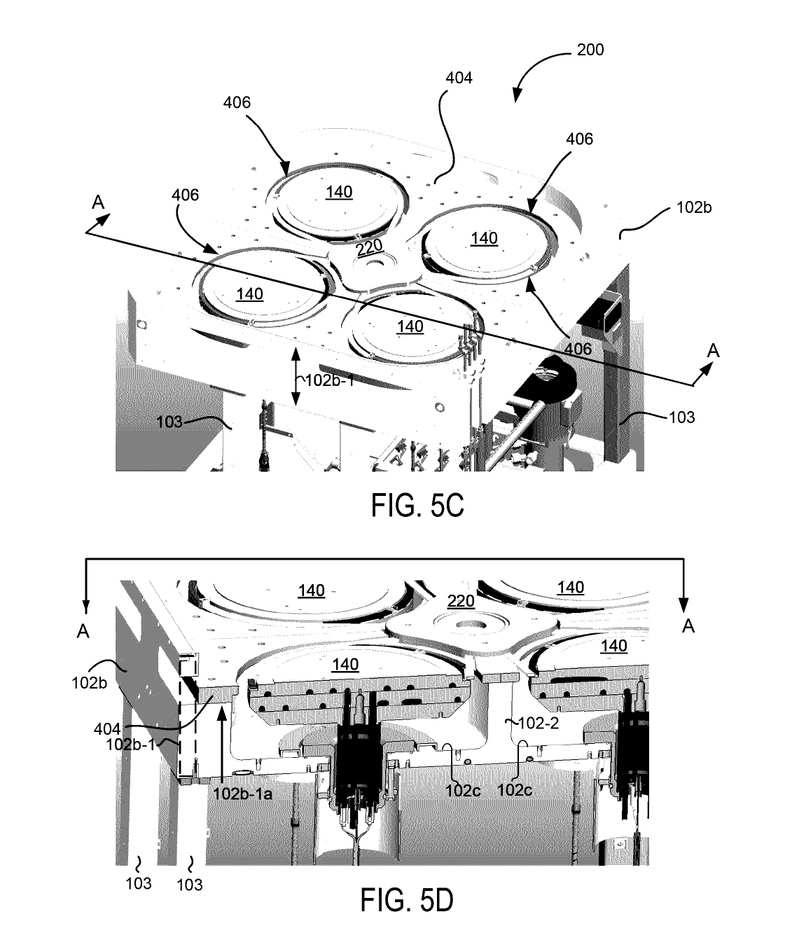

FIG. 5A is a top view of the lower chamber body 202b, which illustrates the positioning of the ground plate 404. As shown, the ground plate 404 will include process openings having a diameter D1, in which pedestal 140 will be disposed. In one embodiment, the pedestals, including the carrier ring 200 will have a diameter D2. In one example configuration, diameter D2 has a size of between about 373 mm and about 406 mm. In a specific embodiment, the diameter D2 is about 378.5 mm. In one example configuration, diameter D1 has a size of between about 413 mm and about 440 mm. In a specific embodiment, the diameter D1 is about 419 mm. Accordingly, a gap defined by the difference between diameter D2 and D1 will be provided, such that the symmetric separation between the pedestal and the ground plate 404 is defined. This configuration allows for sufficient air flow/gas flow to the path between the pedestal 140 and the inner edge of the ground plate 404, defined by the process opening. In this example, the gap is shown as gap 406. In addition, another gap 408 is defined between the inner sidewall of the chamber 102b and the outer edge of the ground plate 404. This gap may be varied depending on tolerances, and in some embodiments may be reduced to a point where the ground plate 404 is touching the inner wall of the lower chamber body 102b. In other embodiments, the gap 408 may be in the range of between about 0 mm and about 5 mm. It should be understood that these example dimensions are simply examples associated with a 300 mm wafer system, and for systems that accommodate larger or smaller wafers, the example dimensions will scale accordingly.

It should be noted that the ground plate 404 provides a substantially symmetric ground potential around the process opening defined by diameter D1, such that the return path to ground is the same all the way around the substrate during processing, which improves process uniformities as well as achieves more stringent control of deposition films. Still further, by improving the ground plate 404 and providing the uniform in substantial symmetric configuration, it is possible to control and reduce non-uniformities between wafers processed in the different stations. This adds to the control of wafer to wafer uniformity as well as repeatability of process in the various stations and during wafer process cycles.

FIG. 5B illustrates a three-dimensional view of the ground plate 404, constructed in accordance with one embodiment. In this example, the process openings are defined to have a diameter D1, as noted above. The diameter D1 is larger than the diameter of the pedestal 140. This difference in diameter will provide for a gap 406 that allows for air flow and for the pumps 162 maintaining the airflow around the substrate 101 and down to the bottom base of the lower chamber body 102b. The illustration in FIG. 5B also shows a center opening 404a that is used to accommodate the rotating mechanism 220. As noted above, the rotating mechanism 220 will also include spider forks 226. In other embodiments, instead of spider forks 226, other lifting mechanisms can be used, which can also be provided with a rotating mechanism 220. Still further, FIG. 5B illustrates an embodiment where the ground plates 404 may optionally be defined by a separate module or parts 404B. This construction is optional, as the ground plate 404 can be defined as a single unit without the illustrated separation lines. In cases where the separation into modular parts is required, each part 404B can be assembled and connected to a multi-station chamber 200.

In one embodiment, the ground plate 404 is a conductive ground plate defined from an alumina material. In some embodiments, the ground plate can be stainless steel. In other embodiments, the ground plate can be a conductive material that is coded with a material. In some examples, the ground plate 404 is defined from any aluminum material, and in one particular example, any non-ferrous material.

FIG. 5C illustrates a three-dimensional view of one example of the multi-station chamber 200 that includes ground plate 404. Ground plate 404 is shown to fit within the lower chamber body 102b. Also shown is the gap 406 defined between the outer edge of the pedestal 140 and the inner edge of the process opening defined in the ground plate 404. As shown, the surrounding wall of the lower chamber body 102b is configured to house the ground plate 404, and the ground plate 404 sits at a level that is just below the outer wall 102b-1.

FIG. 5D shows an illustration of cross section A-A, in accordance with one embodiment. In this example, the ground plate 404 will sit over a support step 102b-1a that is defined from or connected to the outer wall 102b-1. The ground plate 404 In the Ctr. region will sit over the inner walls 102b-2. The ground plate 404 will therefore provide a substantial symmetric cover over the inner region of the lower chamber body 102b that is defined between the inner floor 102c and an under surface of the pedestal 140 and portions of the ground plate 404.

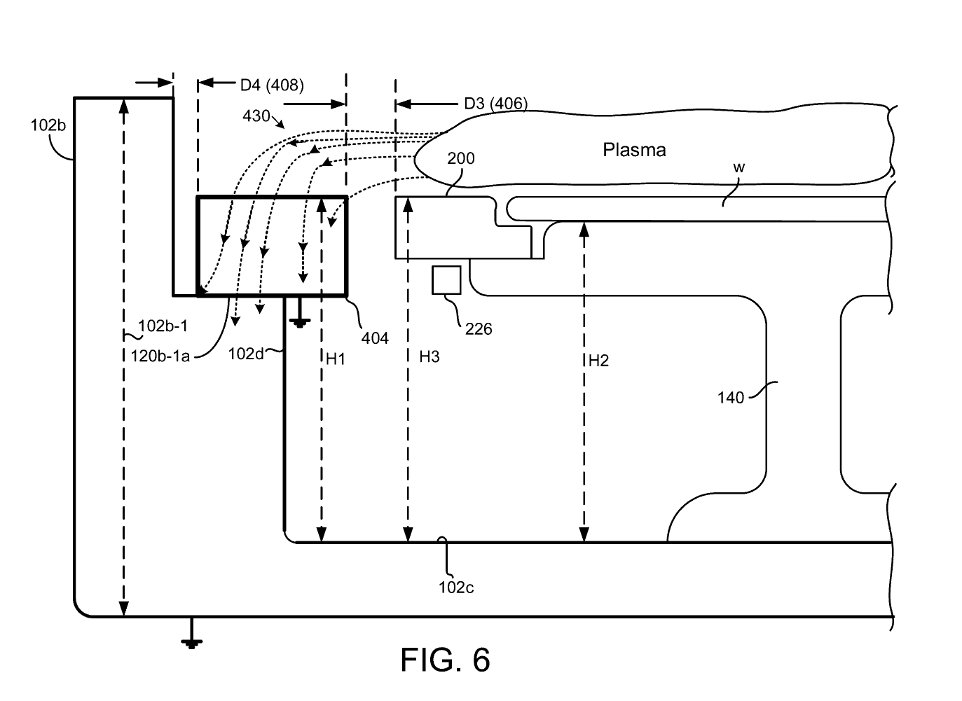

FIG. 6 illustrates a more detailed example diagram of the row plate 404. In this illustration, the ground plate 404 near the outer wall 102b-1 is configured to rest or sit or attached to a support step 102b-1a. As noted above, the ground plate 404 In the Ctr. region may sit over the inner walls 102b-2.

In this example, a first height H1 is defined between the inner floor 102c and a top surface of the ground plate 404. In one embodiment, H1 can have a dimension that is between about 114 mm and about 137 mm. In one configuration, H1 will be about 132 mm.

Also shown is a second height H2 that is defined between the inner floor 102c and a top surface of the pedestal 140. In one embodiment, H1 can have a dimension that is between about 125 mm and about 140 mm. In one configuration, H1 will be about 135.13 mm.

Further shown is a third height H3, that is defined between the inner floor 102c and a top surface of the carrier ring 200. In one embodiment, H3 can have a dimension that is between about 125 mm and about 140 mm. In one configuration, H3 will be about 135.65″ mm.

In one embodiment, a gap 406 will have a dimension D3 that is between about 5 mm and about 30 mm. In one configuration, 406 D3 will be about 20 mm. In still another embodiment, a gap 408 will have a dimension D4 that is between about 0 mm and about 5 mm. In one configuration, 408 D4 will be about 2 mm. By providing the ground plate 404 proximate and surrounding the pedestal 140, the symmetry provided by the gap 406 will enable for a more substantial uniform RF return path the power provided to the chamber, such as the RF returned to ground 430 from the plasma during processing.

Again it should be understood that the above dimensions are provided to provide a detailed understanding of one particular example, and the example relates to 300 mm wafers being processed in the multi-station chamber 102. Suitable adjustments in height and ranges should be considered for chambers that are manufactured to process larger wafers, such as 450 mm wafers, or larger, or even smaller wafer such as 200 mm wafers.

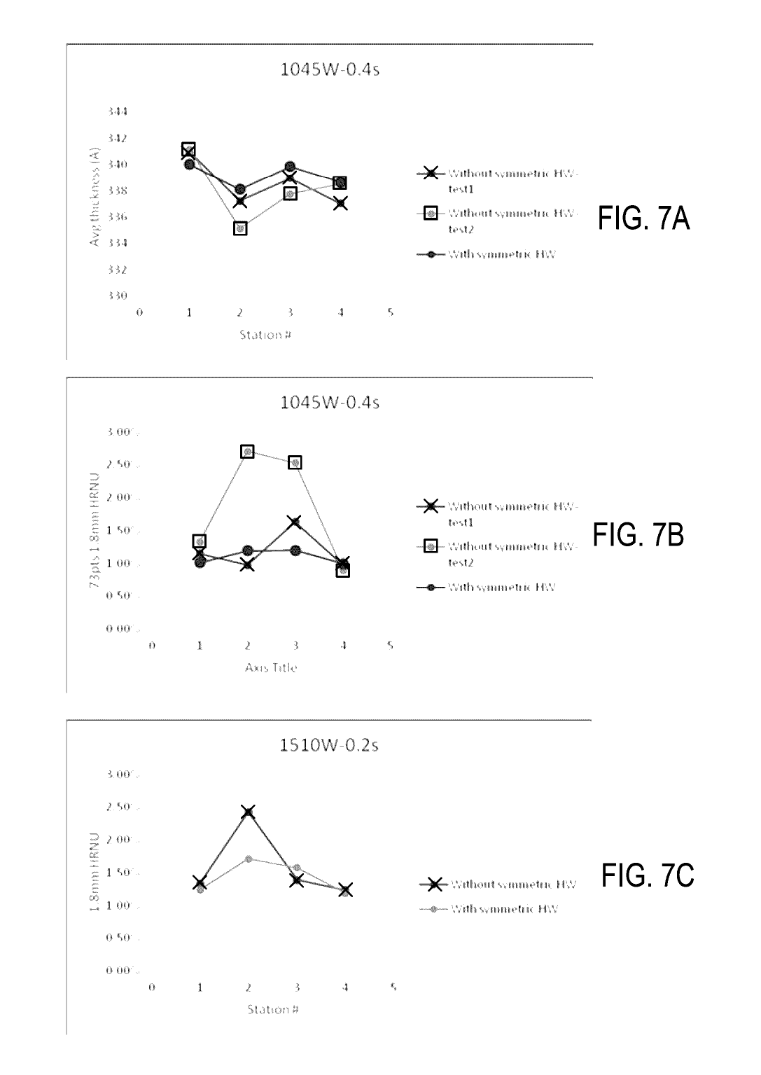

FIG. 7A through 7C illustrate example test data showing substantial improvements and reduce variations between stations 1-4, when the symmetric ground plate 404 is implemented. As shown, without the symmetric ground plate 404, more variation in terms of deposited thicknesses over a substrate are experienced when compared between processes performed in each of the stations 1, 2, 3, and 4. In some cases, such as the one shown in FIGS. 7B and 7C, the process differences between stations can be quite dramatic, but would fit installation of the grounded plate 404, the symmetric return path to ground to the RF power substantially reduces wafer to wafer variations with respect to those wafers processed in different ones of the stations contained within the same chamber. By way of example, tests were conducted to illustrate the improvements with the symmetric ground plate. Without limitation, the following test results are shown in FIGS. 7A-7C.

FIG. 7A shows a graphical comparison of Average thickness (A) versus deposition station. Note that “with symmetric HW (hardware)” has less thickness range than the other two configurations “Without symmetric HW.” Process parameters employed 1045 W (4 stations) for 0.4 s RF time.

FIG. 7B shows a graphical comparison of within wafer non-uniformity (% R/2). Data is shown with and without symmetric HW. “With symmetric HW” has the lowest non-uniformity with 73 pt measurement map at 1.8 mm edge exclusion. Process parameters employed 1045 W (4 stations) for 0.4 s RF time. % R/2 is defined as (mm thickness)−(max thickness)/2×mean*100.

FIG. 7C shows a graphical comparison of within wafer non-uniformity (% R/2). Data is shown with and without symmetric HW. With symmetric HW″ has the lowest non-uniformity with 73 pt measurement map at 1.8 mm edge exclusion. Process parameters employed 1510 W (4 stations) for 0.2 s RF time. % R/2 is defined as (mm thickness)−(max thickness)/2×mean*100.

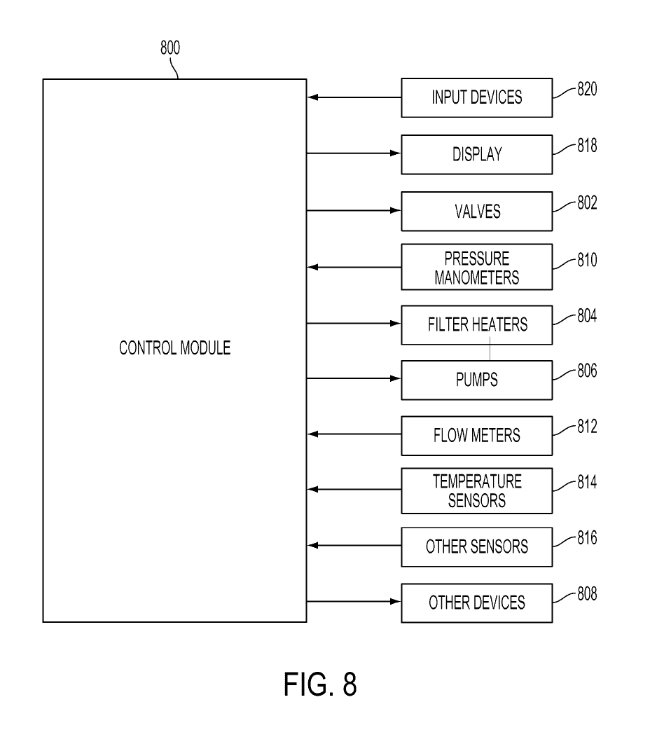

FIG. 8 shows a control module 800 for controlling the systems described above. In one embodiment, the control module 110 of FIG. 1 may include some of the example components. For instance, the control module 800 may include a processor, memory and one or more interfaces. The control module 800 may be employed to control devices in the system based in part on sensed values. For example only, the control module 800 may control one or more of valves 802, filter heaters 804, pumps 806, and other devices 808 based on the sensed values and other control parameters. The control module 800 receives the sensed values from, for example only, pressure manometers 810, flow meters 812, temperature sensors 814, and/or other sensors 816. The control module 800 may also be employed to control process conditions during precursor delivery and deposition of the film. The control module 800 will typically include one or more memory devices and one or more processors.

The control module 800 may control activities of the precursor delivery system and deposition apparatus. The control module 800 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The control module 800 may also monitor the pressure differential and automatically switch vapor precursor delivery from one or more paths to one or more other paths. Other computer programs stored on memory devices associated with the control module 800 may be employed in some embodiments.

Typically there will be a user interface associated with the control module 800. The user interface may include a display 818 (e.g. a display screen and/or graphical software displays of the apparatus and/or process conditions), and user input devices 820 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during deposition include, but are not limited to, mass flow control modules, pressure sensors such as the pressure manometers 810, and thermocouples located in delivery system, the pedestal or chuck (e.g. the temperature sensors 814). Appropriately programmed feedback and control algorithms may be used with data from these sensors to maintain desired process conditions. The foregoing describes implementation of embodiments of the invention in a single or multi-chamber semiconductor processing tool.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

What is claimed is:

1. A multi-station chamber, comprising,
a lower chamber body that includes a plurality of stations arranged around a rotating mechanism, each station includes a pedestal for supporting a substrate and a carrier ring that surrounds the pedestal, the carrier ring of each station is configured to be lifted and moved by the rotating mechanism;
the lower chamber body having an inner floor disposed below each pedestal of each of the plurality of stations;
the lower chamber body having outer walls that surround a perimeter of each of the plurality of stations, the outer walls having a support step;
the lower chamber body having inner walls that laterally separate respective ones of the plurality of stations, wherein the outer walls and the inner walls extend up from the inner floor; and
a ground plate disposed over the support step of the outer walls and over the inner walls, the ground plate having a center opening and a process opening for each station, the process opening defined for each pedestal having the carrier ring, the process opening surrounding the carrier ring of each process station so that gap is symmetrically maintained around and between the ground plate and the carrier ring of each station.

2. The multi-station chamber of claim 1, wherein the ground plate is positioned at a height relative to the inner floor of the lower chamber, that is about equal to a top surface of a substrate when present over any one of the plurality of stations.

3. The multi-station chamber of claim 1, wherein the ground plate covers a top surface of the lower chamber, except for the center opening and the process opening for each station.

4. The multi-station chamber of claim 1, wherein the process opening of each station has a first diameter that is larger than a second diameter of the carrier ring of each station.

5. The multi-station chamber of claim 1, wherein the center opening is covered by the rotating mechanism, wherein the rotating mechanism includes a plurality of spider forks, each of the spider forks is associated with each of the plurality of stations and is configured to lift and move a respective one of carrier rings from each station.

6. The multi-station chamber of claim 1, wherein a symmetric separation is defined between each process opening of the ground plate and an outer edge of each carrier ring from each station.

7. The multi-station chamber of claim 6, wherein the symmetric separation provides a ground potential, provided by the ground plate, symmetrically around each substrate when disposed over a respective pedestal of each station.

8. The multi-station chamber of claim 1, further comprising,
a top chamber body, the top chamber body is configured to mate over the lower chamber body, wherein the top chamber body includes a plurality of showerheads, each showerhead is configured to be aligned over a respective pedestal of a respective station.

9. The multi-station chamber of claim 8, wherein radio frequency (RF) power is configured to be provided to either the showerhead or the pedestal of each station, wherein the RF power is provided a ground return via the ground plate that surrounds each process opening of each station.

10. The multi-station chamber of claim 1, wherein the ground plate is assembled in modular sections, each modular section corresponding to each one of the stations, wherein when the modular sections are assembled the modular sections present a continuous ground plane.

11. The multi-station chamber of claim 1, wherein the ground plate extends up to the outer walls, wherein a separation is defined between the outer walls and the ground plate, the ground configured to be electrically coupled to the outer walls via the support step that is coupled to the ground plate, wherein the support step is located at one or more locations along the inner walls of the lower chamber body.

12. The multi-station chamber of claim 1, further comprising,
a pump disposed below the lower chamber body, the pump is configured to provide evacuation of process gases from a space between the inner floor and an under surface of the ground plate, wherein process gases flow through the gap at each station that is symmetrically maintained around and between the process openings in the ground plate and the carrier ring of each station.

13. A multi-station chamber, comprising,
the multi-station chamber includes four stations, the four stations are arranged in a square configuration with a rotating mechanism in a center location;
a pedestal for supporting a substrate is provided for each of the four stations, each pedestal disposed in a lower chamber body, each pedestal including a carrier ring;
the lower chamber body includes outer walls and inner walls to define a space for each of the pedestals of the four chambers;
a ground plate disposed over the inner walls and attached to the outer walls, the ground plate having a center opening and a process opening for each station, the center opening is configured to receive the rotating mechanism at the center location, wherein the process opening has a diameter that is larger than a diameter of the carrier ring at each station, wherein a symmetric gap is defined between an edge of each process opening defined by the ground plate and an outer edge of a carrier ring; and
an upper chamber body, the upper chamber body is configured to mate over the lower chamber body, wherein the upper chamber body includes four showerheads, each of the four showerheads is configured to be aligned over a respective pedestal of a respective station;
wherein radio frequency (RF) power is configured to be provided to either the showerhead or the pedestal of each station, wherein the RF power is provided a ground return via the ground plate that symmetrically surrounds each process opening of each station.

14. The multi-station chamber of claim 13, wherein a top surface of the ground plate is positioned at a first height relative to an inner floor of the lower chamber, the first height is about equal to or slightly less than a second height of a top surface of the pedestal relative to the inner floor of the lower chamber, such that a top surface of a substrate when present over any one of the four stations is substantially coplanar with the top surface of the ground plate.

15. The multi-station chamber of claim 13, wherein the ground plate covers a top surface of the lower chamber, except for the center opening and the process opening for each station.

16. The multi-station chamber of claim 13, wherein the rotating mechanism includes a plurality of spider forks, each of the spider forks is associated with each of the four of stations and is configured to lift and move a respective one of carrier rings from each station in order to lift and move a respective substrate when present over a respective pedestal.

17. The multi-station chamber of claim 13, wherein the symmetric gap provides a separation to a ground potential provided by the ground plate, the ground potential is symmetrically arranged around each substrate when disposed over a respective pedestal of each station.

18. A multi-station chamber, comprising,
the multi-station chamber include four stations, the four stations are arranged in a square configuration with a substrate handling mechanism;
a pedestal for supporting a substrate is provided for each of the four stations, each pedestal disposed in a lower chamber body, each pedestal including a carrier ring;
the lower chamber body includes outer walls and inner walls to define a space for each of the pedestals of the four chambers;
a ground plate disposed over the inner walls and attached to the outer walls, the ground plate having a center opening and a process opening for each station, the center opening is configured to receive the substrate handling mechanism, wherein the process opening has a diameter that is larger than a diameter of the carrier ring at each station, wherein a symmetric gap is defined between an edge of each process opening defined by the ground plate and an outer edge of a carrier ring; and
an upper chamber body, the upper chamber body is configured to mate over the lower chamber body, wherein the upper chamber body includes four showerheads, each of the four showerheads is configured to be aligned over a respective pedestal of a respective station;
wherein during operation a radio frequency (RF) power is configured to be provided to either the showerhead or the pedestal of each station, wherein the RF power is provided a ground return via the ground plate that symmetrically surrounds each process opening of each station.
wherein the ground plate is defined by modular sections, each module section corresponding to each one of the stations, wherein when the modular sections are assembled the modular sections present a continuous coplanar surface.

19. The multi-station chamber of claim 18, wherein the substrate handling mechanism includes spider forks for lifting and moving the carrier rings between stations.

20. The multi-station chamber of claim 18, further comprising,
a pump disposed below the lower chamber body, the pump is configured to provide evacuation of process gases from a space between an inner floor and an under surface of the ground plate, wherein process gases flow through the symmetric gap at each station that is maintained around and between the process openings in the ground plate and the carrier ring of each station.
